(19) United States
(12) Patent Application Publication
(10) Pub. No.: US 2022/0082200 A1
(43) Pub. Date: Mar. 17, 2022

(54) ELECTRONIC DEVICE STANDS

(71) Applicant: Hewlett-Packard Development Company, L.P., Spring, TX (US)

(72) Inventors: Nishit Gupta, Houston, TX (US); Dimitre D. Mehandjiysky, Spring, TX (US)

(73) Assignee: Hewlett-Packard Development Company, L.P., Spring, TX (US)

(21) Appl. No.: 17/419,746

(22) PCT Filed: Jun. 4, 2019
(86) PCT No.: PCT/US2019/035406

§ 371 Date: Dec. 10, 2020

(51) Int. Cl. F16M 11/04; F16B 1/00; F16M 11/38; H05K 7/02; H05K 5/00; H02J 7/00; H02J 50/10; H01F 7/02

(52) U.S. Cl. CPC F16M 11/041; F16B 1/00; F16M 11/38; H05K 7/02; F16B 2001/0035; H02J 7/0044; H02J 50/10; H01F 7/02; H05K 5/0017

(57) ABSTRACT

Example stands for electronic devices are disclosed. In an example, the stand includes a base, an elongate column extending upward from the base, and an attachment surface pivotably coupled to the column. In addition, the stand includes a plurality of magnets coupled to the mounting surface. The magnets are to attract magnets within the electronic device.

### BACKGROUND

The use of mobile electronic devices, such as laptop computers, tablets computers, smart phones, etc., is becoming more wide spread. For instance, advancements in wireless internet connectivity, electronics miniaturization, and processing speeds (among other factors) have allowed these smaller, more mobile electronic devices to dominate personal and even professional computing operations.

### BRIEF DESCRIPTION OF THE DRAWINGS

Various examples will be described below referring to the following figures:

FIG. 1 is a rear view of an electronic device according to some examples;

FIG. 2 is a perspective view of an electronic device for mounting on the stand of FIG. 1 according to some examples;

FIG. 3 is a rear view of a system including the stand of FIG. 1 and the electronic device of FIG. 2 according to some examples;

FIG. 4 is a rear view of the system of FIG. 3 with the electronic device rotated to a portrait orientation according to some examples;

FIG. 5 is a rear view of the system of FIG. 3 with the electronic device drawn closer to a base of the stand according to some examples;

FIGS. 6 and 7 are side views of the system of FIG. 3 showing different orientations for the electronic device according to some examples;

FIG. 8 is a schematic view of the base of the stand of FIG. 1 according to some examples;

FIG. 9 is a schematic view of a connection between an attachment surface of the stand of FIG. 1 and the electronic device of FIG. 2 according to some examples; and

FIG. 10 is a schematic view of an accessory device and the base of the stand of FIG. 1 according to some examples.

### DETAILED DESCRIPTION

In the figures, certain features and components disclosed herein may be shown exaggerated in scale or in somewhat schematic form, and some details of certain elements may not be shown in the interest of clarity and conciseness. In some of the figures, in order to improve clarity and conciseness, a component or an aspect of a component may be omitted.

In the following discussion and in the claims, the terms “including” and “comprising” are used in an open-ended fashion, and thus should be interpreted to mean “including, but not limited to . . . .” Also, the term “couple” or “couples” is intended to be broad enough to encompass both indirect and direct connections. Thus, if a first device couples to a second device, that connection may be through a direct connection or through an indirect connection via other devices, components, and connections. In addition, as used herein, the terms “axial” and “axially” generally refer to positions along or parallel to a central or longitudinal axis (e.g., central axis of a body or a port), while the terms “lateral” and “laterally” generally refer to positions located or spaced to the side of the central or longitudinal axis. As used herein, the term “elongate” when used in reference to a member or object, means that the object has a length that is greater than its width.

As used herein, including in the claims, the word “or” is used in an inclusive manner. For example, “A or B” means any of the following: “A” alone, “B” alone, or both “A” and “B.” In addition, when used herein including the claims, the word “generally” or “substantially” means within a range of plus or minus 10% of the stated value.

As used herein, the term “display” refers to an electronic display (e.g., a liquid crystal display (LCD), a plasma display, etc.) that is to display images generated by an associated computing device. The term “flexible display” refers to an electronic display that may be deformed (e.g., rolled, folded, etc.) within a given parameter or specification (e.g., a minimum radius of curvature) without losing electrical function or connectivity. As used herein, the term “electronic device,” refers to a device that is to carry out machine readable instructions, and may include internal components, such as, processors, power sources, memory devices, etc. For example, an electronic device may include, among other things, a personal computer, a smart phone, a tablet computer, a laptop computer, a personal data assistant, etc.

As previously described, the use of mobile electronic devices is becoming more wide spread in both the personal and professional computing markets. While mobility has been a factor to the success of such devices, there is still a need for devices that may be used within established work stations for certain types of computing activities. Accordingly, examples disclosed herein include stands for electronic devices (and systems including the stands) that are to provide an established workstation that may support a mobile electronic device. In some implementations, the disclosed example stands may include features and assemblies for supporting or enhancing computing operations with the mobile electronic device.

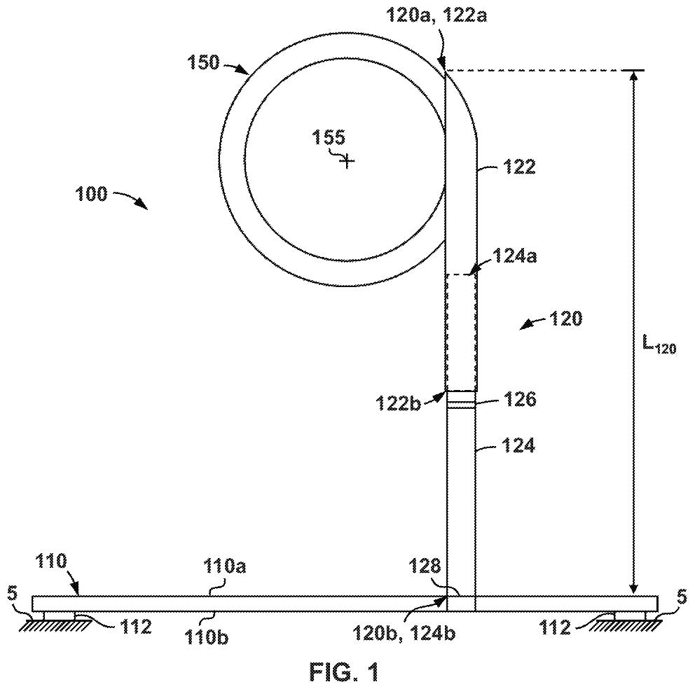

Referring now to FIG. 1, a stand 100 for an electronic device (not shown) according to some examples is shown. Generally speaking, stand 100 includes a base 110, an elongate column 120, and an attachment surface 150 pivotably coupled to column 120.

In some examples, base 110 includes a first or top side 110a, and a second or bottom side 110b opposite top side 110a. In addition, base 110 includes a plurality of feet 112 disposed along bottom side 110b that are to engage with a support surface 5 during operations. Support surface 5 may be any suitable surface for supporting stand 100, such as, for example, a table, desk, countertop, floor, etc. In some examples, bottom side 110b may engage directly with the support surface 5, and in other examples, a single foot (e.g., foot 112) may be disposed on bottom side 110b for engaging with support surface 5.

Column 120 includes a first or upper end 120a, and a second or lower end 120b. Lower end 120b is pivotably coupled to base 110 at a hinge 128. In addition, as will be described in more detail below, attachment surface 150 is coupled to column 120 at or proximate to upper end 120a. Also, column 120 includes a length L₁₂₀ extending along column 120 from lower end 120b to upper end 120a. In some examples, column 120 is “elongate,” and thus, the length L₁₂₀ of column 120 is greater than the maximum width of column 120.

In some examples (e.g., such the example of FIG. 1), column 120 comprises a first column member 122, and a second column member 124 coupled to the first column member 122. First column member 122 includes a first or upper end 122a and a second or lower end 122b opposite upper end 122a. Also, second column member 124 includes a first end or upper end 124a, and a second or lower end 124b opposite upper end 124a. The upper end 122a of first column member 122 is coincident with the upper end 120a of column 120, and lower end 124b of lower column member 124 is coincident with lower end 120b of column 120. Upper end 124a of second column member 124 may be longitudinally and telescopically received within first column member 122. As will be described in more detail below, first column member 122 may be telescoped relative to second column member 124 so as to selectively adjust length L₁₂₀ during operations.

Second column member 124 includes a hinge 126 disposed between upper end 124a and lower end 124b. During operations second column member 124 (and thus column 120 more generally) may be pivoted about hinges 128, 126. As will be described in more detail below, pivoting column 120 about hinges 126, 128 may allow an electronic device mounted to attachment surface 150 to be placed in a number of different orientations and positions.

Referring still to FIG. 1, attachment surface 150 comprises a ring that is pivotably coupled to column 120 at (or proximate to) upper end 120a. Further details of examples of attachment surface 150 are disclosed below. However, generally speaking, attachment surface 150 is pivotably mounted to column 120 such that attachment surface 150 may rotate or pivot about an axis of rotation 155 between a plurality of positions. Any suitable coupling between attachment surface 150 and column 120 may be used to facilitate the pivoting of attachment surface 150 about axis 155 during operations. For instance, in some examples, a bearing (not shown) may be disposed within column 120 (particularly within first column member 122) that engages with and supports attachment surface 150. In some examples, either attachment surface 150 or column 120 (particularly first column member 122) may include a slot, and the other of the attachment surface 150 and column 120 may include a projection that is received within the slot. Thus, during operations, pivoting of attachment surface 150 about axis 155 may be accomplished by slidingly engaging the projection along the slot. Still other methods of pivotably coupling attachment surface 150 to column 120 may be used in other examples.

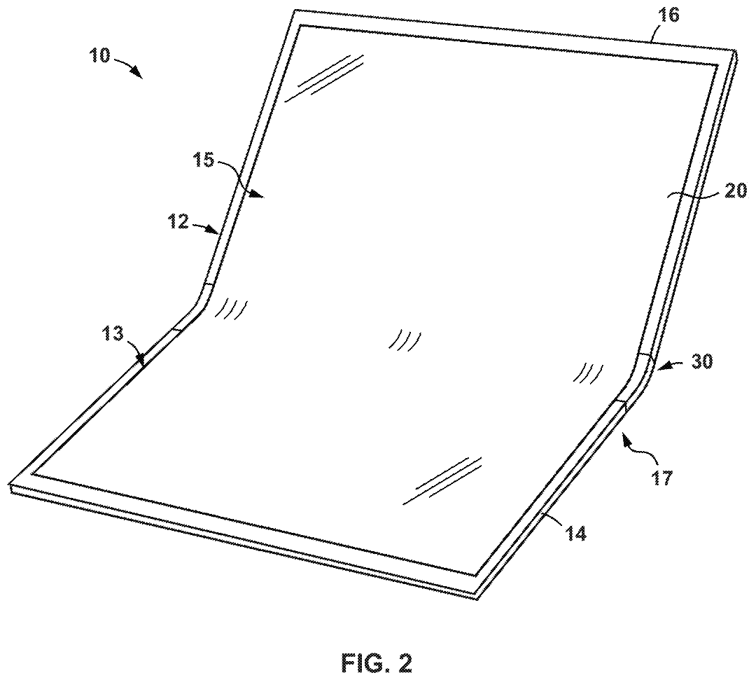

Referring now to FIG. 2, an electronic device 10 that may be mounted to and supported by stand 100 is shown. Electronic device 10 is a mobile device that includes a housing 12 and a flexible display 20 partially disposed within the housing 12.

Housing 12 includes a first housing member 14 and a second housing member 16. The first and second housing members 14, 16 are rotatably coupled to one another at a hinge 30. Thus, first housing member 14 may rotate about the hinge 30 relative to second housing member 16, and second housing member 16 may rotate about hinge 30 relative to first housing member 14.

Flexible display 20 (or more simply “display 20”) is disposed within housing 12, but is accessible for viewing and interaction by a user through an opening 13 formed by the first housing member 14 and second housing member 16 on a first or front side 15 of housing 12. A side of housing 12 that is opposite the front side 15 (and thus opposite display 20) may be referred to herein as a second or back side 17 of housing 12. Generally speaking, display 20 is to display images for viewing by the user based on machine readable instructions carried out by electronic components (e.g., processor(s)) (not shown) within electronic device 10. In some examples, display 20 is a touch sensitive display that is to communicate with other electronic components (not shown) within electronic device 10 to detect touch inputs by a user on display 20 during operations. In other examples, display 20 may not be touch sensitive. Display 20 may utilize any suitable display technology such as, for example, LCD, plasma, light emitting diode (LED)-LCD, organic-LED-LCD, etc.

In addition, as previously described, display 20 is a flexible display, and thus, display 20 may be deformed, bent, rolled, etc., within acceptable parameters or specifications while maintaining electrical function and connectivity with other components (not shown) within electronic device 10. Thus, when first housing member 14 and second housing member 16 are rotated about hinge 30 relative to one another as previously described above, display 20 is to deform (e.g., roll or bend) proximate to hinge 30 in order to accommodate the relative rotation between the housing members 14, 16.

During operations, housing 12 of electronic device 10 may be transitioned between an open position, and a closed position (or folded position). Specifically, in the closed position, second housing member 16 is rotated about hinge 30 toward first housing member 14 so that front side 15 and display 20 are concealed by housing members 14, 16. In some examples, housing members 14, 16 are in contact with one another when housing 12 is in the closed position. In some examples, the closed position is useful for when a user is transporting the electronic device 10 from one location to another or for when the electronic device 10 is being stored within a bag, pocket, or other compartment. In the open position, the second housing member 16 is rotated about hinge 30 away from first housing member 14, to thereby expose display 20. In some examples, the open position may include a plurality of rotational positions for second housing member 16 relative to first housing member 14 about hinge 30. For instance, in some examples, when housing 12 is in the open position, the second housing member 16 is flat, flush, or co-planar with the first housing member 14 such that display 20 laid flat (e.g., in this position, housing members 14, 16 may be disposed approximately 180° from one another about hinge 30).

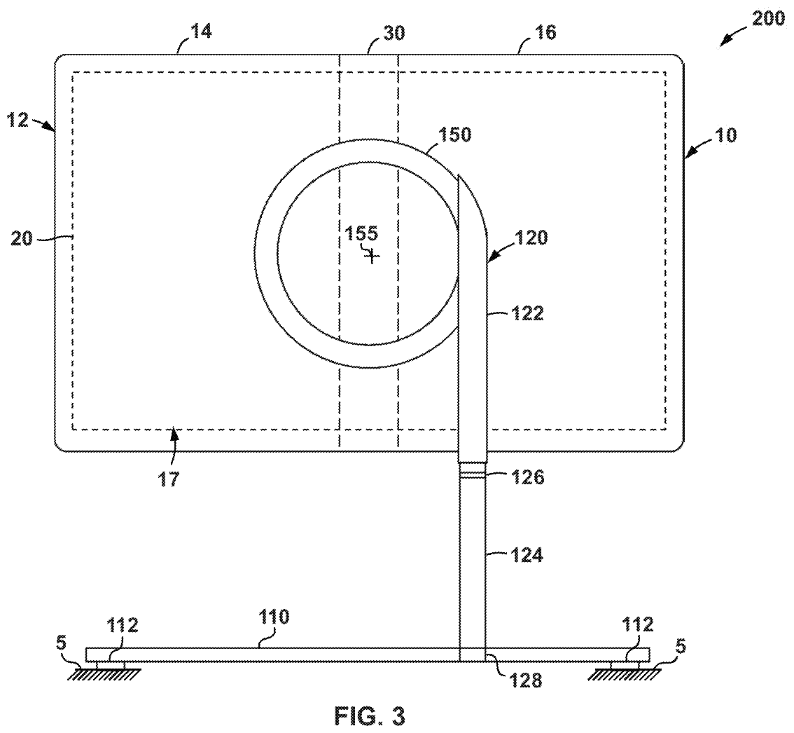

Referring now to FIGS. 3-5, a system 200 including the electronic device 10 supported by the stand 100 is shown. In particular, housing 12 (including housing members 14, 16) is placed in the fully open position (such that housing members 14, 16 are co-planar or flat about hinge 30 as previously described), and the back side 17 of housing 12 is engaged with and supported on attachment surface 150 of stand 100. As a result, electronic device 10 is supported above support surface 5 via stand 100 during operations. As will be described in more detail below, in some examples, housing 12 of electronic device 10 is secured to attachment surface 150 via a magnetic attraction between corresponding magnets (e.g., permanent magnets, electromagnets, a combination thereof, etc.) disposed in housing 12 and attachment surface 150.

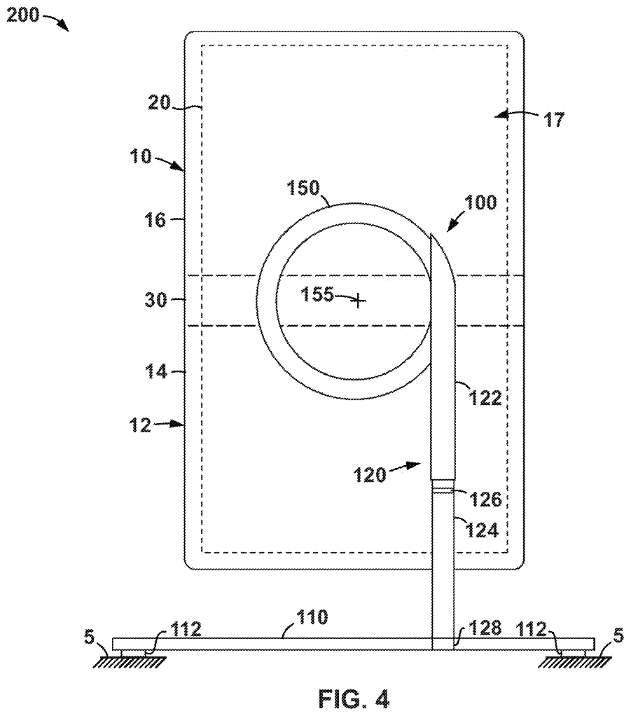

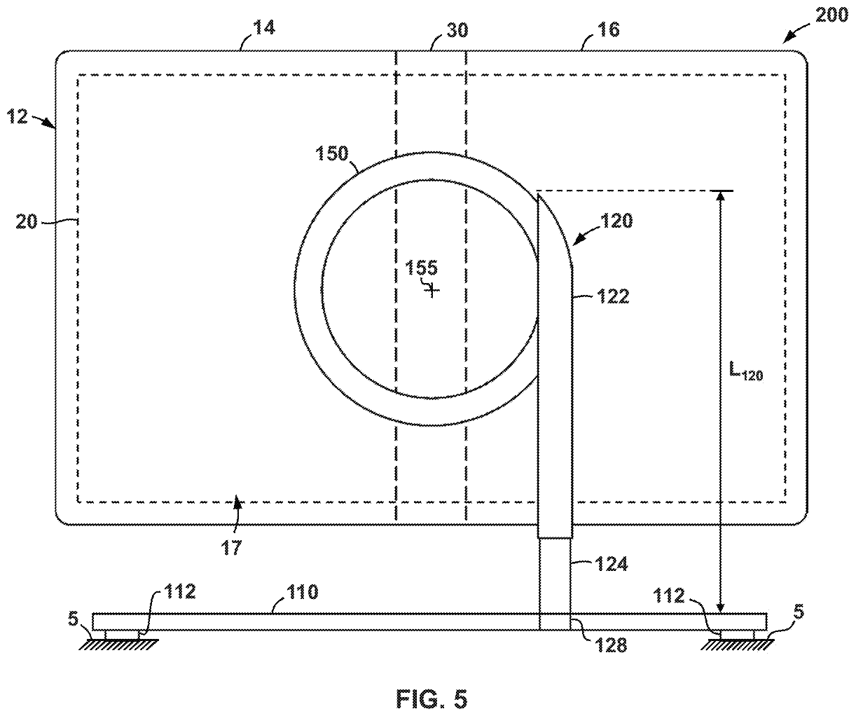

Once electronic device 10 is mounted to attachment surface 150, the position and orientation of electronic device 10 may be adjusted via manipulation of stand 100. For instance, as shown in FIGS. 3 and 4, electronic device 10 (and particularly display 20 of electronic device 10) may be rotated between a landscape orientation as shown in FIG. 3 and a portrait orientation as shown in FIG. 4 by rotating attachment surface 150 relative to column 120 in the manner described above. Thus, in some examples, attachment surface 150 may rotate or pivot 90° or more about axis 155 during operations. As shown in FIGS. 3 and 4, axis of rotation 155 extends perpendicularly through electronic device 10 (including display 20) when electronic device 10 is mounted to attachment surface 150 as previously described. In addition, as shown in FIGS. 3 and 5, the height of electronic device 10 (or the distance between base 110 and electronic device 10) may be adjusted by telescoping first column member 122 over second column member 124 (to thereby decrease the length L₁₂₀ in FIG. 1).

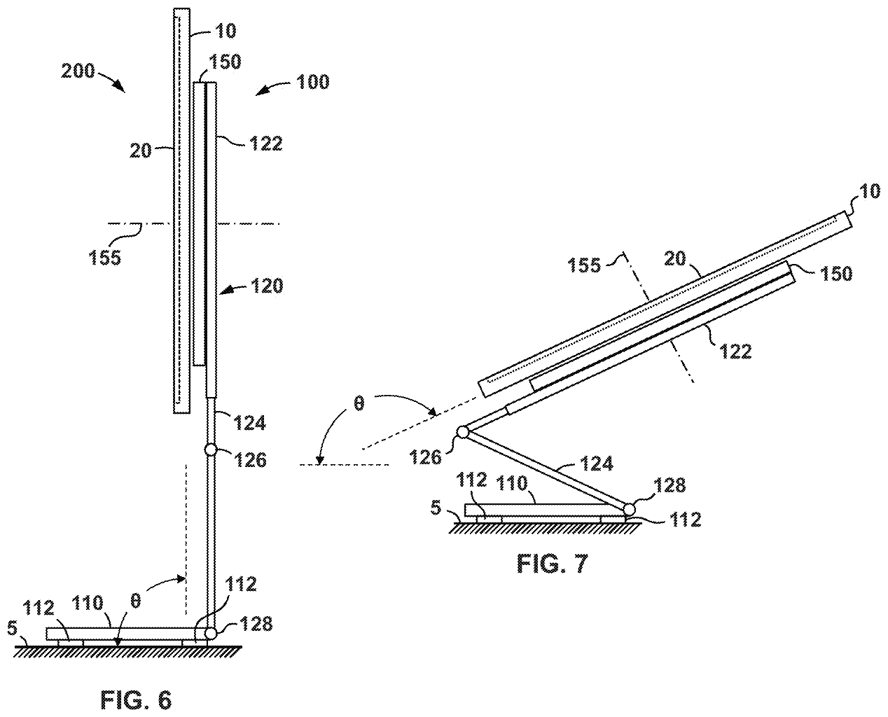

Referring now to FIGS. 6 and 7, in some examples column 120 may be selectively pivoted about hinges 126, 128 so as to place electronic device 10 (and particularly display 20) in a desired orientation for a user. In particular, in some examples, an angle θ between electronic device 10 (particularly with display 20) and support surface 5 and/or base 110 of stand 100 may be approximately 90° when column 120 extends vertically upward from base 110 as shown in FIG. 5. This position, shown in FIG. 5, may be useful for when a user is viewing the display 20 of electronic device 10 from a sitting position or at a work station (e.g., such as a desk). However, if the user would like to interact with display 20 or view display 20 at a declined angle (e.g., such as when a user is performing touch inputs on the display 20 with a stylus or with the user's finger(s)), column 120 may be pivoted about hinges 126, 128 to increase the angle θ (e.g., to a value generally greater than 90° and less than or equal to 180°). Specifically, to accomplish this adjustment in the angle of electronic device 10 (e.g., namely display 20) relative to support surface 5 and/or base 110 of stand 100, second column member 124 may be pivoted about hinge 126 and hinge 128. In some circumstances, rotations of electronic device 10 and attachment surface 150 about hinge 126 may allow display 20 of electronic device 10 to achieve a desired angle with base 110 and support surface 5 (i.e., the angle θ); and rotations of second column member 124 about hinge 128 may allow display 20 to be placed at a desired distance or height above support surface 5 (or base 110). Hinges 126, 128 may be torqued (e.g., by built in friction, biasing members, etc.) so that the desired angle θ of display 20 may be maintained by hinges 126, 128 after the forces supplied by the user to manipulate the stand 100 are removed.

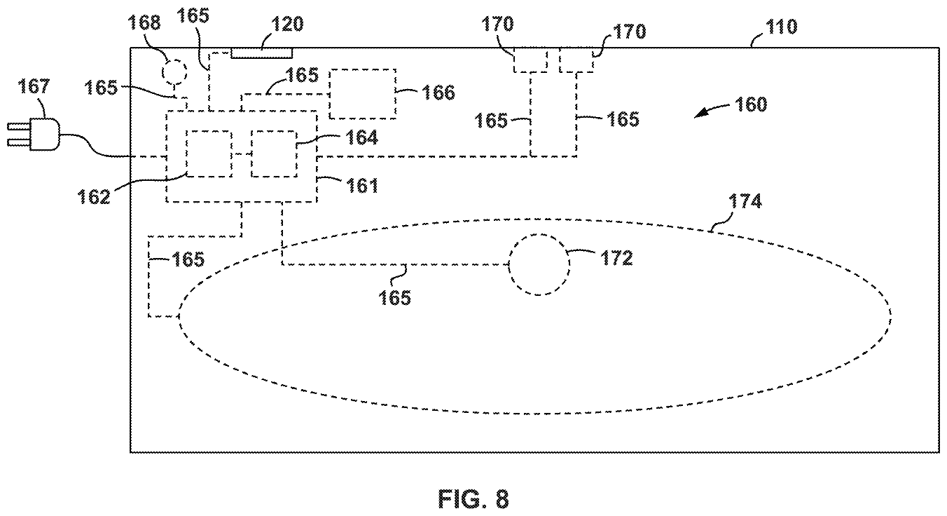

Referring now to FIG. 8, in this example, stand 100 includes a control assembly 160 that is disposed within base 110. As will be described in more detail below, control assembly 160 includes a controller 161 that may be communicatively coupled to electronic device 10 when electronic device 10 is supported on attachment surface 150 of stand 100.

Controller 161 may comprise any suitable device or assembly which is capable of receiving an electrical (or other data) signal and transmitting various electrical (or other data) signals to other devices (e.g., such as electronic device 10). In particular, in this example, controller 161 includes a processor 162 and a memory 164. The processor 162 (e.g., microprocessor, central processing unit, or collection of such processor devices, etc.) executes machine readable instructions provided on memory 164 to provide the processor 162 with all of the functionality described herein. The memory 164 may comprise volatile storage (e.g., random access memory), non-volatile storage (e.g., flash storage, read only memory, etc.), or combinations of both volatile and non-volatile storage. Data consumed or produced by the machine readable instructions can also be stored on memory 164.

In addition, control assembly 160 includes a communication antenna 168 that is coupled to controller 161. Communication antenna 168 is to send and receive wireless communication signals to and from, respectively, another device or a plurality of other devices (e.g., an accessory device, electronic device 10, etc.). Communication antenna 168 may utilize any suitable wireless communication technology, such as, for example, BLUETOOTH®, WIFI, radio frequency (RF) communication, infrared communications, acoustic communications, etc. Signals sent by antenna 168 are generated in controller 161 (e.g., by processor 162) and communicated to antenna 168 such that antenna 168 may communicate the received signals to another device (or a plurality of other devices). Conversely, signals received by antenna 168 are communicated to controller 161 such that additional actions or functions may be carried out by processor 162 in response thereto. In some examples, antenna 168 may communicate with a wireless network, such as a local WIFI connection, a telecommunications network, etc.

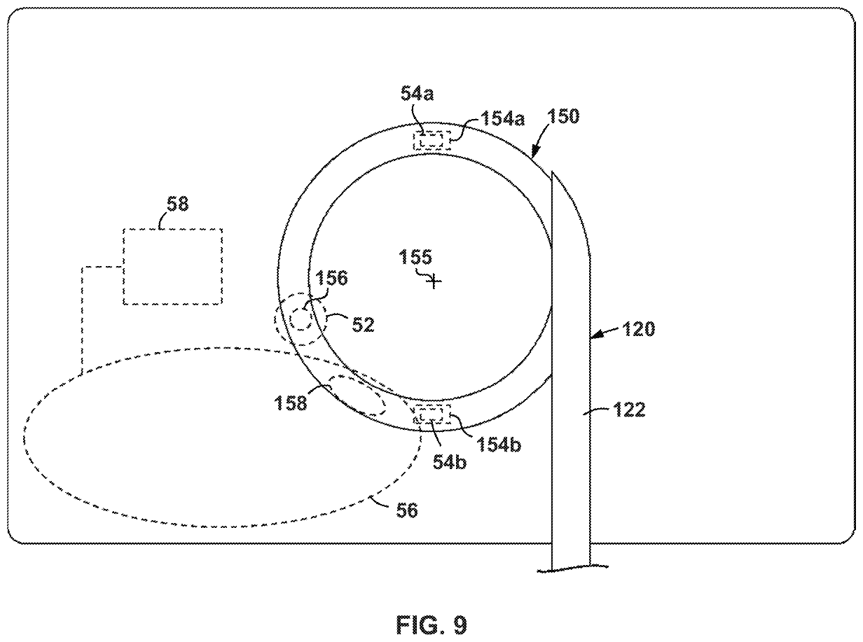

Referring still to FIGS. 8 and 9, control assembly 160 also includes a power source 166 disposed within base 110. Power source 166 provides electrical power to other electronic components within stand 100 (and possibly also within electronic device 10 as described in more detail below) (e.g., controller 161, antenna 168, etc.). Power source 166 may comprise any suitable source of electrical power such as, for example, a battery, capacitor, a converter or transformer, etc. In this example, power source 166 is a rechargeable battery. In addition, in some examples, control assembly 160 may also receive electrical power from a wall plug 167 that may be inserted within an available electrical outlet (not shown). In particular, wall plug 167 may supply electrical power for operating the components within control assembly 160 and/or for charging power source 166. In some examples, power source 166 is not included in control assembly 160, and all electrical power is supplied by wall plug 167.

In some examples, control assembly 160 includes a wireless charging coil 174 and a proximity sensor 172 that are disposed within base 110. The sensor 172 and coil 174 are electrically coupled to controller 161, such that electrical current and/or data signals may flow between coil 174, sensor 172 and controller 161 during operations. Further, in some examples, control assembly 160 comprises a plurality of ports 170 disposed along base 110 that are coupled to controller 161. Ports 170 may comprise any input, output, or combination port that is to receive or engage with a plug or cable that may be coupled other devices (e.g., accessory devices such as keyboards, mice, trackpads, styluses, etc.) or networks. For instance, ports 170 may be arranged to connect to USB (universal serial bus) style connectors, Ethernet style connectors, or some combination thereof, etc.

The power source 166, antenna 168, ports 170, coil 174, sensor 172, wall plug 167, etc., may all be coupled to controller 161 within control assembly 160 via a plurality of conductors 165. Conductors 165 may comprise any suitable conductive conduit, path, and the like for conducting electrical, light, or other signals therealong during operations. For instance, in some examples, conductors 165 (or some of the conductors 165) may comprise conductive wires, fiber optic lines, conductive traces, etc. In addition, in some examples, some portion of the components of control assembly 160 may communicate wirelessly with controller 161.

Referring now to FIG. 9, as previously described above, attachment surface 150 of stand 100 may include a plurality of magnets disposed therein that are to attract corresponding magnets within housing 12 of electronic device 10 in some examples. For instance, in the example of FIG. 9, electronic device 10 is secured to attachment surface 150 via a magnetic attraction between a plurality of magnets 154 disposed within attachment surface 150 and a corresponding plurality of magnets 54 disposed within housing 12 of electronic device 10. In some examples, the magnets 154, 54 are to attract to one another when a particular, predetermined orientation (e.g., rotational orientation about axis 155) is achieved between electronic device 10 and attachment surface 150. For instance, in some examples, the polarity of magnets 154, 54 may be adjusted such that magnets 54 are attracted to the magnets 154 in a particular relative rotational orientation of electronic device 10 and attachment surface 150 about axis 155.

More specifically, in the example of FIG. 9, a total of two magnets 154 are mounted within attachment surface 150 and are designated as magnets 154a, 154b, and a total of two corresponding magnets 54 are mounted within housing 12 of electronic device 10 and are designated as magnets 54a, 54b. In some examples, the polarity of magnets 54a, 154b may be positive, and the polarity of magnets 54b, 154a may be negative. Thus, in these examples, when electronic device 10 is to be mounted to attachment surface 150, device 10 is to be rotated about axis 155 such that magnet 54a is brought proximate to magnet 154a, and magnet 54b is brought proximate magnet 154b. Because magnets 54a, 154a and magnets 54b, 154b have opposite polarity, they are attracted to one another to thereby attach and hold electronic device 10 on attachment surface 150.

Magnets 154a, 154b, and magnets 54a, 54b may be any type of magnet, such as, for instance, permanent magnets, electromagnets, or a combination thereof. In examples where magnets 154a, 154b and/or magnets 54a, 54b are electromagnets, the polarity of such magnets may be altered or changed between negative and positive by changing a direction of flow of electrical current through the magnet (which may comprise a coil of electrically conductive wiring). In examples where magnets 154a, 154b and/or magnets 54a, 54b are permanent magnets, the polarity of such magnets may be altered by changing an orientation of the magnet within the corresponding housing (e.g., housing 12, attachment surface 150, etc.). In particular, because a permanent magnet may have two poles disposed along different sides or surfaces thereof, the orientation of the permanent magnet may be altered (e.g., within housing 12 in the case of magnets 54a, 54b or within attachment surface 150 in the case of magnets 154a, 154b) so as to direct or place a surface associated with a particular polarity (e.g., negative or positive) toward or proximate to, respectively, the attachment point of the housing 12 and attachment surface 150. In examples where magnets 154a, 154b (or one of the magnets 154a, 154b) are electromagnets, magnets 154a, 154b may be coupled to (and thus energized by) controller 161 in base 110. In particular, in some examples, magnets 154a, 154b (or one of the magnets 154a, 154b) is couple to controller 161 with a conductor or a plurality of conductors (such as e.g., conductors 165, not shown) that extend through column 120.

Referring still to FIGS. 8 and 9, attachment surface 150 may also include a proximity sensor 156 and charging coil 158 disposed therein. Proximity sensor 156 may be a magnetic sensor that senses or detects a surrounding magnetic field (e.g., such as would be generated by a magnet). Charging coil 158 may comprise an inductive charging coil to deliver and/or receive electrical power with a corresponding charging coil disposed within another device (e.g., electronic device 10). In some examples, both charging coil 158 and sensor 156 are coupled to controller 161 of control assembly 160 disposed within base 110 (see FIG. 7). In particular, in some examples, coil 158 and sensor 156 are coupled to controller 161 via a conductor (e.g., a conductor 165 extending through column 120), a wireless connection, or combination thereof (not specifically shown in FIG. 9).

During operations, when electronic device 10 is secured to attachment surface 150 via attracted magnets 154a, 154b, 54a, 54b as previously described, a magnet 52 and a charging coil 56 that are both disposed within housing 12 may be aligned and placed in relatively close proximity to proximity sensor 156 and charging coil 158, respectively. The proximity sensor 156 may sense the magnetic field generated by magnet 52 and therefore sense that presence of electronic device 10 on stand 100. Thereafter, sensor 156 may generate a signal which is communicated to controller 161 so that controller may initiate various routines and/or functions. In some examples, proximity sensor 156 may sense the magnetic field generated by one (or both) of the magnets 54a, 54b. As a result, in some of these examples, electronic device 10 does not include an additional magnet 52.

In some examples, upon sensing the physical connection of electronic device 10 to attachment surface 150, controller 161 may initiate a connection protocol whereby a wireless connection is established between controller 161 and a suitable controller or control assembly (not shown) within electronic device 10 via communications antenna 168. Thereafter, control assembly 160 may supplement or even replace functionality of the electronic device 10 during operations. As an example, following the establishment of a wireless connection between control assembly 160 and electronic device 10, control assembly 160 may provide processing functionality (e.g., via processor 162) to assist electronic device 10 with performing tasks and functions. As another example, memory 164 may be utilized as an memory source for electronic device 10 (e.g., memory 164 may function as an external drive for saving data, machine readable instructions, etc.). As still another example, ports 170 may be physically connected to other devices (e.g., accessory devices such as keyboards, mice, trackpads, styluses, etc.) and/or networks (e.g., a server, a local network, the internet, etc.) via appropriate cabling, wires, etc. Thus, once electronic device 10 is mounted to attachment surface 150 and control assembly 160 establishes a wireless connection with electronic device 10 in the manner described above, additional connections between the electronic device 10 and the additional devices or networks may be accomplished (or supplemented) via the connections provided at ports 170.

Referring still to FIGS. 8 and 9, once electronic device 10 is mounted to attachment surface 150 and control assembly 160 establishes a wireless connection with electronic device 10 in the manner described above, controller 161 may direct electrical current toward and through charging coil 158 disposed within attachment surface 150 so as to induce a flow of electricity in charging coil 56 and thereby charge a power source 58 (e.g., which may comprise a battery, capacitor, etc.) within electronic device 10. More particularly, in some examples, the flow of electric current through charging coil 158 generates a magnetic field which further induces a corresponding flow of electrical current through the charging coil 56 in electronic device 10. This induced electrical current in charging coil 56 flows back to power source 58 to thereby increase the electrical charge thereof. In some examples, controller 161 may first determine if power source 58 is below some minimum power threshold (e.g., such as minimum charge percentage of full capacity) by querying electronic device 10 (or a controller disposed therein) via antenna 168. If controller 161 determines that power source 58 is below a first threshold (e.g., 50%, 60%, 70%, 80%, etc., of full capacity), controller 161 may then direct electrical current to charging coil 158 to charge power source 58 as previously described. These charging operations may continue until controller 161 determines that the charge of power source 58 has reached (or is above) a predetermined second threshold (e.g., 60%, 70%, 80%, 90%, 99%, 100%, etc., of full capacity) that is greater than the first threshold.

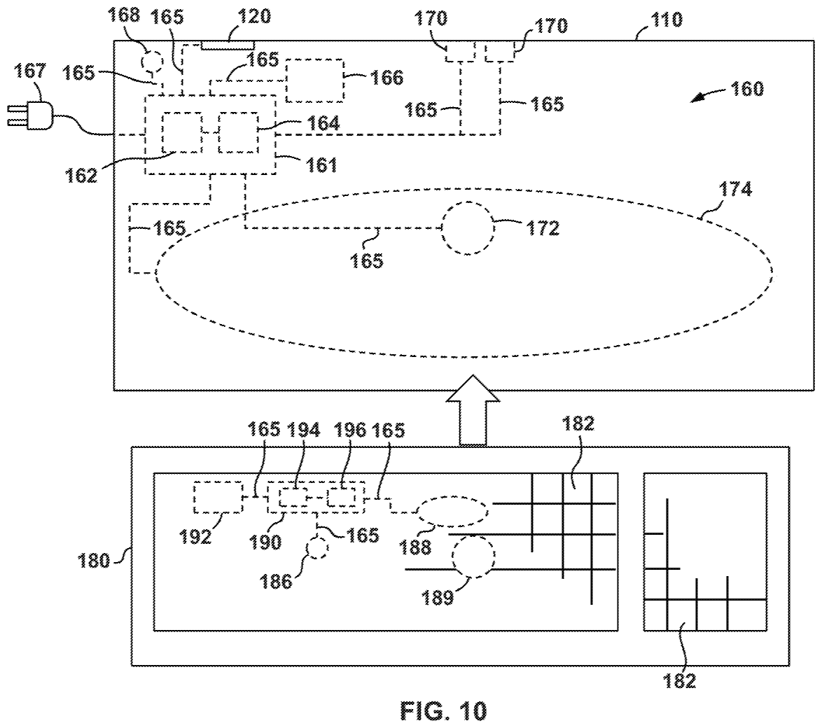

Referring now to FIG. 10, in some examples, base 110 may serve as a connection and/or charging platform for various accessory devices (e.g., keyboard, mouse, stylus, etc.) or even other electronic devices (e.g., smart phones, other computing devices). For instance, an accessory device 180 is shown in FIG. 10 that may be used with electronic device 10 during operations. For example, in this implementation, accessory device 180 is a wireless keyboard that includes a plurality of keys or buttons 182 that are to be engaged by a user to provide inputs to an electronic device (e.g., electronic device 10) during operation thereof. Accordingly, for purposes of describing this implementation, accessory device 180 may be referred to as keyboard 180. However, any other suitable accessory device may be used in other examples.

Keyboard 180 includes a magnet 189 which may be either disposed within keyboard 180 or disposed along an outer surface thereof. In this example, magnet 189 is internally disposed within keyboard 180. Magnet 189 may be any suitable magnet or magnetic device that is to generate an magnetic field. In some examples, magnet 189 is an electromagnet, and in other examples, magnet 189 is a permanent magnet. In this example, magnet 189 is a permanent magnet comprising a permanently magnetic material.

Referring still to FIG. 10, keyboard 180 further includes a controller 190, a power source 192, a wireless communication antenna 186, and a charging coil 188. Charging coil 188 is electrically coupled to controller 190 and power source 192 via an electrical conductor 165.

Controller 190 includes a processor 194 and a memory 196. Wireless communication antenna 186 is coupled to controller 190 via an electrical conductor 165 such that antenna 186 is to send and receive signals to and from other devices or networks (e.g., control assembly 160, electronic device 10, etc.) during operations. Power source 192 (which is a rechargeable battery in this example) is coupled to controller 190 via an electrical conductor 165 to provide electrical power to controller 190 and other components within keyboard 180 (e.g., antenna 186, charging coil 188, etc.). Processor 194, memory 196, power source 192, and communication antenna 186 are generally the same to processor 162, memory 164, power source 166, and antenna 168, respectively, of control assembly 160 in base 110. Thus, the same general description of processor 162, memory 164, power source 166, and antenna 168 of control assembly 160 may be applied to describe processor 194, memory 196, power source 192, and communication antenna 186, respectively, in keyboard 180.

During operations when keyboard 180 is placed on top side 110a (see e.g., FIG. 1) of base 110, a routine (or plurality of routines) may be triggered within control assembly 160. Initially, control assembly 160 within base 110 may sense the presence of keyboard 180 on top side 110a via proximity sensor 172. Specifically, when keyboard 180 is placed on top side 110a of base 110, the magnet 189 is placed proximate to proximity sensor 172. In some examples, keyboard 180 may include a plurality of magnets (e.g., such as that described above for magnet 189) such that keyboard 180 may be placed on base 110 (specifically top side 110a) in a number of different orientations while still allowing one of the plurality of magnets to be in relatively close proximity to proximity sensor 172. In this example, proximity sensor 172 may be implemented as a magnetic sensor. Proximity sensor 172 is to sense a magnetic field (e.g., the magnetic field generated by magnet 189). Once the strength of the magnetic field sensed by proximity sensor 172 reaches a predetermined threshold, controller 161 (e.g., processor 162) within base 110 determines that keyboard 180 is disposed on top side 110a of base 110 and initiates further routines.

In some examples, upon sensing the presence of keyboard 180 on top side 110a, controller 161 may determine whether a wireless connection is established between the electronic device 10 and the keyboard 180. More specifically, controller 161 may determine whether a wireless connection is established between the communication antenna 186 in keyboard 180 and a corresponding antenna (not shown) disposed within electronic device 10. When a user has already utilized keyboard 180 to provide inputs to electronic device 10, this connection may already be established. If controller 161 determines that no wireless connection exists with keyboard 180 (e.g., such as when the user has not previously utilized keyboard 180 to provide inputs on electronic device 10 or when a previous wireless connection has been lost or removed), the controller 161 may then prompt electronic device 10 (e.g., via the connection between controller 161 and electronic device 10 via antenna 168 previously described above) to establish a wireless connection between keyboard 180 (e.g., via antenna 186) (e.g., controller 161 may trigger electronic device 10 to initiate a wireless pairing sequence) such that wireless communication between keyboard 180 and electronic device 10 is established.

In some examples, upon sensing the presence of keyboard 180 on top side 110a (e.g., via proximity sensor 172), controller 161 may initiate a wireless pairing operation to establish wireless communication between keyboard 180 and control assembly 160. In turn, inputs generated by keyboard 180 (e.g., when a user presses a key or button 182) are communicated to controller 161, which then communicates the inputs to electronic device 10 via the wireless communication established between electronic device 10 and control assembly 160 previously described above. In these examples, wireless communication between keyboard 180 and control assembly 160 may be established via antennas 168, 186.

Referring still to FIG. 10, in some examples, upon sensing the presence of keyboard 180 on top side 110a of base 110, control assembly 160 may initiate a wireless charging operation for power source 192 in keyboard 180. For instance, in some examples, the arrangement of proximity sensor 172 and charging coil 174 may be such that when magnet 189 (or one of a plurality of such magnets) is aligned or in proximity to proximity sensor 172, charging coil 174 is aligned (or is proximate to) charging coil 188 in keyboard 180. As a result, controller 161 may direct electrical current to charging coil 174 so as to inductively induce a corresponding electrical current in charging coil 188, which is then delivered to power source 192 such that power source 192 may be charged. In particular, the flow of electric current through charging coil 174 generates a magnetic field which further induces a corresponding flow of electrical current through the charging coil 188 in keyboard 180. This induced electrical current in charging coil 188 flows back to power source 192 in keyboard 180 to thereby increase the electrical charge of power source 192.

In examples where a wireless connection is established between control assembly 160 and keyboard 180 (e.g., via antennas 168, 186), controller 161 may first determine (e.g., via the established wireless connection) whether power source 192 is below a predetermined power threshold to initiate the above described inductive charging operations. More specifically, in some examples, controller 161 may determine whether power source 192 within keyboard 180 has a predetermined minimum amount of electrical charge. For instance, controller assembly 160 may determine the charge of power source 192 (e.g., as a percentage of full capacity). When the determined electrical charge of power source 192 is below a predetermined first threshold (e.g., 50%, 60%, 70%, 80%, etc., of full capacity), then controller 161 may induce an electric current through charging coil 174 in base 110 as previously described. This charging sequence may continue until controller 161 determines that the charge of power source 192 has reached (or is above) a predetermined second threshold (e.g., 60%, 70%, 80%, 90%, 99%, 100%, etc., of full capacity). As a result, the predetermined second threshold may be greater than the predetermined first threshold. Thereafter, controller 161 stops the flow of electric current to charging coil 174 and the charging operation of power source 192 in keyboard 180 is ceased.

While various examples have been described herein, additional examples and modifications are further contemplated. For instance, referring again to FIGS. 8 and 9, in some examples, electronic device 10 may be disposed on top of base 110 (on top side 110a) such that wireless charging of power source 58 may be accomplished via charging coils 56 and 174 in the manner previously described above. In some examples, electronic device 10 may comprise another type or design of mobile electronic device (e.g., a tablet computer). In some example, a display of the mobile electronic device (e.g., display 20) may not be a flexible display. In some examples, base 110 (or some other portion of stand 100) may include speakers to emit sounds or sound effects generated by the electronic device 10.

As described herein, example stands (e.g., stand 100) that provide an established workstation for electronic devices, such as mobile electronic devices (e.g., electronic device 10) have been disclosed. As a result, through use of the disclosed stands, the use and function of such electronic devices may be enhanced and improved.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications.

What is claimed is:

1. A stand for an electronic device, the stand comprising:
a base;
an elongate column extending upward from the base;
an attachment surface pivotably coupled to the column; and
a plurality of magnets coupled to the mounting surface, wherein the magnets are to attract magnets within the electronic device.

2. The stand of claim 1, comprising:
a first hinge on the column between the base and the attachment surface; and
a second hinge coupled between the column and the base.

3. The stand of claim 1, wherein the column has a length that is to be adjusted to selectively move the attachment surface toward or away from the base.

4. The stand of claim 1, wherein the attachment surface comprises a ring that is pivotably coupled to an upper end of the column.

5. The stand of claim 4, wherein the ring is to pivot relative to the column about an axis of rotation that is to extend perpendicularly through the electronic device.

6. The stand of claim 1, comprising a control assembly to establish a wireless connection with the electronic device, when the electronic device is coupled to the attachment surface.

7. The stand of claim 6, wherein the control assembly comprises an inductive charging coil to charge a power source disposed within the electronic device.

8. A system, comprising:
an electronic device comprising a display; and
a stand to support the electronic device, the stand comprising:
a base;
an elongate column extending upward from the base;
an attachment surface pivotably coupled to the column; and
a plurality of magnets coupled to the attachment surface, wherein the magnets are to attract magnets within the electronic device.

9. The system of claim 8, wherein the attachment surface comprises a ring that is pivotably coupled to an upper end of the column.

10. The system of claim 9, wherein the ring is to pivot relative to the column about an axis of rotation that extends perpendicularly through the electronic device.

11. The system of claim 8, wherein the plurality of magnets are to attract the magnets within the electronic device so as to place the electronic device in a preselected orientation relative to the attachment surface.

12. The system of claim 8, comprising:
an accessory device; and
an inductive charging coil within the base, wherein the inductive charging coil is to charge a power source within the accessory device when the accessory device is placed atop the base.

13. The system of claim 12, wherein the base comprises a controller that is to establish a connection with the electronic device when the electronic device is coupled to the attachment surface.

14. A system, comprising:
an electronic device comprising a display; and
a stand to support the electronic device, the stand comprising:
a base;
an elongate column extending upward from the base;
ring pivotably coupled to the column; and
a plurality of magnets coupled to the ring, wherein the magnets are to attract magnets within the electronic device to attach the electronic device to the ring in a pre-determined orientation.

15. The system of claim 14, wherein the ring is to pivot relative to the column about an axis of rotation that extends through the electronic device, when the electronic device is attached to the ring.
